(19) United States
(12) Patent Application Publication
(10) Pub. No.: US 2006/0203448 A1
(43) Pub. Date: Sep. 14, 2006

(54) Display apparatus

(76) Inventor: Gyu Jung, Yongin-si (KR)

Correspondence Address: STANZIONE & KIM, LLP, 919 18TH STREET, N.W., SUITE 440, WASHINGTON, DC, 20006, US

(21) Appl. No.: 11/320,797

(22) Filed: Dec. 30, 2005

(30) Foreign Application Priority Data
Mar. 8, 2005 (KR) 2005-19357

(51) Int. Cl. H05K 7/20

(52) U.S. Cl. 361/695; 361/702

(57) ABSTRACT

The invention relates to a display apparatus, including a front cover having a display part for displaying an image attached thereon; a rear cover coupled with the front cover and having a hole provided therein; a circuit part attached with the front cover and/or the rear cover; a POD card-mounting part arranged on the circuit part; a guide part to couple the POD card-mounting part with the hole to discharge heat; and a POD fan arranged between the POD card-mounting part and the hole.

### CROSS-REFERENCE TO RELATED APPLICATION

This application claims priority to and the benefit of Korean Patent Application No. 10-2005-0019357, filed on Mar. 8, 2005, which is hereby incorporated by reference for all purposes as if fully set forth herein.

### BACKGROUND OF INVENTION

1. Field of the Invention

The present invention relates to a display apparatus, and more particularly, to an improved cooling structure for a point of deployment card (POD).

2. Description of the Related Art

A display apparatus refers to an electronic instrument, such as a monitor and a television etc., that displays data on a screen.

A display apparatus using a cathode ray tube (CRT) displays images with high quality; however, such devices are thicker or deeper than flat panel display devices due to structural characteristics. The CRT is divided into a color display tube (CDT) which may be used for a computer monitor and a color picture tube (CPT) which may be used for a television.

A conventional CRT display apparatus includes a casing formed with an air outlet; a POD (Point Of Deployment) card-mounting part provided in the casing and mounting the POD card; and a POD fan provided on an upper side of the POD card-mounting part.

The POD fan discharges heat generated from the POD card to outside and keeps the POD card at a sufficiently cool temperature.

Although the conventional display apparatus discharges heat generated by the POD card, some heat may still be generated or input inside the casing. Such heat decreases the cooling efficiency of the POD fan, and adversely affects various components inside the casing, such a print circuit board (PCB).

### SUMMARY OF THE INVENTION

The present invention provides a display apparatus that is capable of discharging heat generated from a POD card to outside.

Additional features of the invention will be set forth in the description which follows, and in part will be apparent from the description, or may be learned by practice of the invention.

The present invention discloses display apparatus, including a front cover having a display part for displaying an image attached thereon; a rear cover coupled with the front cover and having a hole provided therein; a circuit part attached with the front cover and/or the rear cover; a POD card-mounting part arranged on the circuit part; a guide part to couple the POD card-mounting part with the hole to discharge heat; and a POD fan arranged between the POD card-mounting part and the hole.

The present invention also discloses a display apparatus, including a front cover having a display part for displaying an image attached thereon; a rear cover coupled with the front cover and having a hole provided therein; a circuit part attached with the front cover and/or the rear cover; a POD card-mounting part arranged on the circuit part; a guide part to couple the POD card-mounting part with the hole to discharge heat; and a POD fan arranged between the POD card-mounting part and the guide part.

The present invention also discloses a display apparatus, including a front cover having a display part displaying an image attached thereon; a rear cover coupled with the front cover and having a hole provided therein; a circuit part attached with the front cover and/or the rear cover; a POD card-mounting part arranged on the circuit part; a guide part to couple the POD card-mounting part with the hole to discharge heat; and a POD fan arranged between the guide part and the hole.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a perspective view of a display apparatus according to an embodiment of the invention.

FIG. 2 is an exploded perspective view of the display apparatus according to the embodiment of the invention shown in FIG. 1.

FIG. 3 is a perspective view showing a mounting structure of a PCB of the display apparatus according to the embodiment of the invention shown in FIG. 1.

FIG. 4 is a perspective view showing a cooling structure of a POD card of the display apparatus according to the embodiment of the invention shown in FIG. 1.

FIG. 5 is a sectional view showing the cooling structure of the POD card of the display apparatus according to the embodiment of the invention.

### DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It is understood that when an element or layer is referred to as being “on” or “connected to” or “connected with” another element or layer, it can be directly on or directly connected to or with the other element or layer or intervening elements or layers may be present.

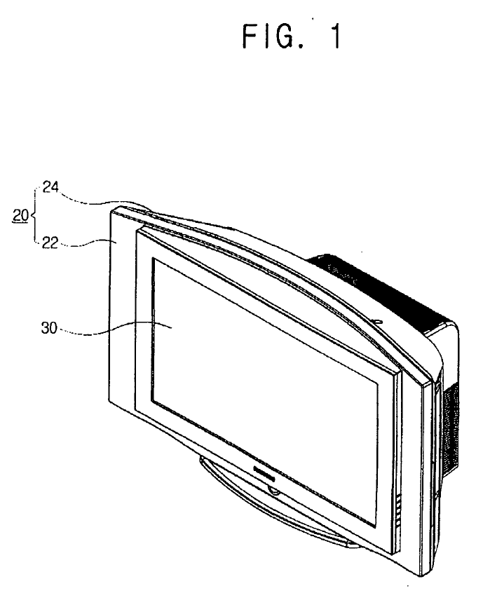

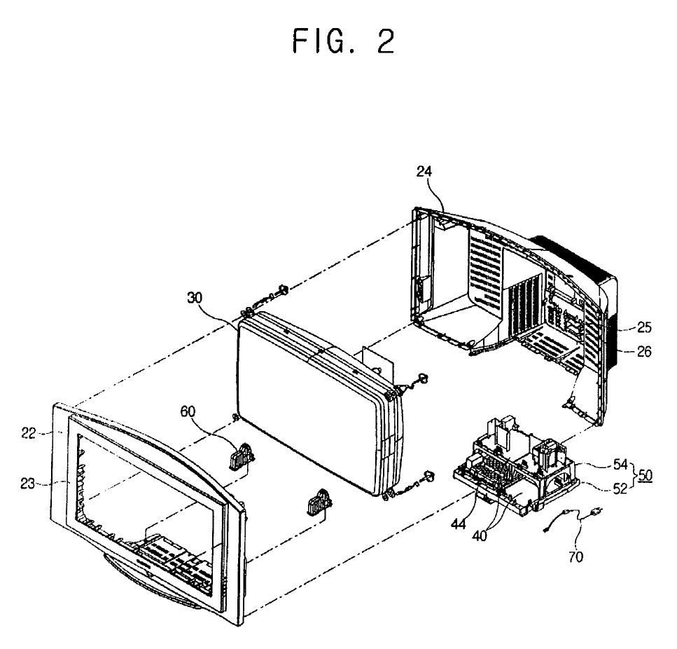

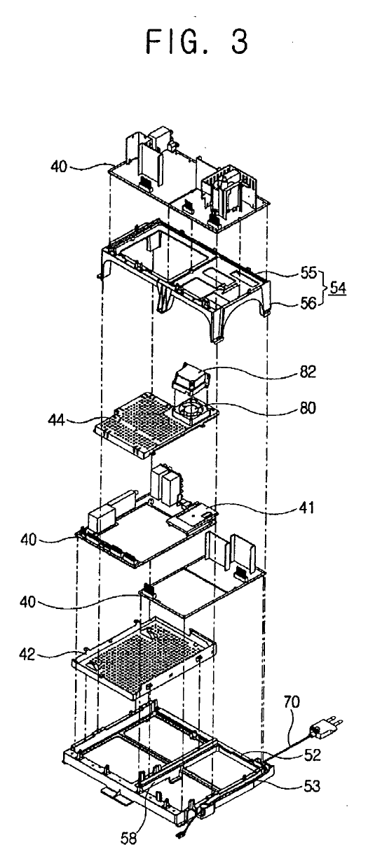

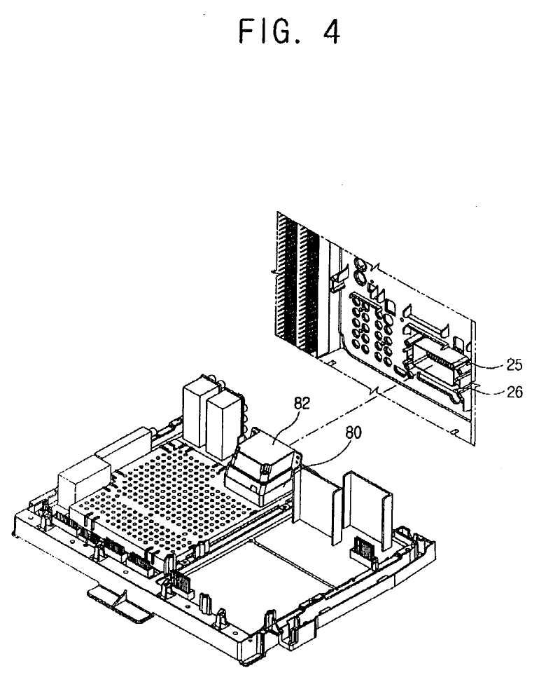

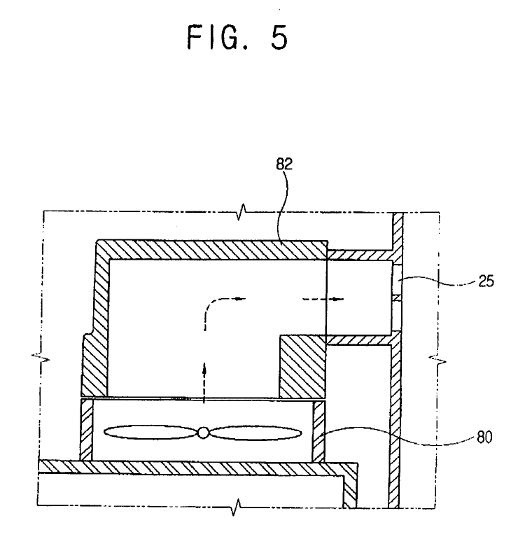

As shown in FIGS. 1, 2, 3, 4 and 5, according to an embodiment of the invention, a display apparatus includes a casing 20 forming an exterior appearance of the display apparatus; a cathode ray tube 30 provided in the casing 20 and displaying images; a plurality of PCBs (print circuit board) 40 provided in the casing 20; and a substrate bracket 50 provided in the casing 20 and mounting or attaching the PCBs 40 with the casing 20.

The casing 20 includes a front cover 22 provided in front of the cathode ray tube 30 and having an opening in the middle to expose the cathode ray tube 30, and a rear cover 24 provided at the back of the cathode ray tube 30 and coupled with the front cover 22. A cover mask 23 may be coupled with the front cover 22 to protect the CRT 30. The front cover 22 may have a substantially rectangular shape. The rear cover 24 may be formed with or include an air outlet 25 and a POD card insert hole 26.

The cathode ray tube 30 has a thin-type structure as compared with a conventional CRT 30, and may be spaced from a bottom or base portion of the casing 20 and coupled in front of the casing 20. It is understood that the cathode ray tube 30 is not limited to the above described embodiment and may employ other configurations.

A pair of supporting members 60 spaced apart at a predetermined distance to sufficiently support the cathode ray tube 30 are provided between the bottom of the casing 20 are a lower part of the cathode ray tube 30.

The plurality of the PCBs 40 may be applied to a power PCB, a system PCB, a deflection PCB etc. Each PCB is provided with circuit components such as an integrated circuit etc.

The substrate bracket 50 is mounted or attached to the casing 20 to stack and hold the plurality of the PCBs 40, thereby increasing room utilization and compactly composing the appearance of the casing 20. The substrate bracket 50 includes a first bracket 52 provided at the bottom of the casing 20 and mounting the PCBs 40, and a second bracket 54 detachably coupled with an upper side of the first bracket 52 and mounting or supporting the PCBs 40. For example, some PCBs 40 are provided in the first bracket 52 and other PCBs 40 are provided in the second bracket 54 as a stack-like structure.

The first bracket 52 may be formed with or include a cable supporter 53 to accommodate, contain, house, or support a power cable 70 or wire.

The second bracket 54 includes a base 55 that is spaced apart from the first bracket 52 at a predetermined distance. The second bracket 54 mounts the PCBs 40 at an upper part thereof. The second bracket 54 includes a supporting rib 56 that extends from the base 55 and is coupled with the first bracket 52. For example, the supporting rib 56 may be downward extending.

The supporting rib 56 provides space for mounting at least one of the PCBs 40. The structure of the supporting rib 56 may change variously to accommodate the PCBs 40 mounted thereunder.

The first bracket 52 may include a divisional partition 58 to divide and mount a plurality of PCBs 40. Alternatively, the second bracket 54 may be formed with the same divisional partition 58 as the first bracket 52.

One of the plurality of the PCBs 40 includes a POD card-mounting part 41 for mounting a POD card (not shown) that is inserted through a POD card insert hole 26. The POD and insert hole 26 may be formed in the rear cover 24. A POD fan 80 is mounted at an upper side of the POD card-mounting part 41 to discharge heat generated from the POD card (not shown) to the outside of the display device. It is understood that the POD fan 80 is not limited to being provided in the above described position of the display device.

An upper portion of the POD fan 80 may be coupled with a guide part 82 that guides the heat ventilated via the POD fan 80 to an air outlet 25 formed in the rear cover 24.

The guide part 82 may be provided between the POD fan 80 and the air outlet 25. The guide part 82 may be formed having a duct-like structure so that the heat ventilated via the POD fan 80 is not input to the inside of the casing 20. For example, a first side of the guide part 82 may be coupled with the POD fan 80 and a second side thereof may be coupled with the air outlet 25.

The structure, position, and materials of the guide part 82 may be changed to alter the flow of the discharged heat in order to improve the cooling efficiency of the POD fan 80.

Reference number 42 is a shield case and reference number 44 is a shield cover.

According to the embodiments of the invention described above, the heat ventilated from the POD fan via the guide part is directly guided to the air outlet, thereby improving the cooling efficiency of the POD card.

Therefore, the prevent invention substantially prevents the heat ventilated from the POD fan from being input inside the casing.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display apparatus, comprising:
a front cover having a display part for displaying an image attached thereon;
a rear cover coupled with the front cover and having a hole provided therein;
a circuit part attached with the front cover and/or the rear cover;
a POD card-mounting part arranged on the circuit part;
a guide part to couple the POD card-mounting part with the hole to discharge heat; and
a POD fan arranged between the POD card-mounting part and the hole.

2. The display apparatus of claim 1, wherein the POD fan is arranged on an upper side of the POD card-mounting part.

3. The display apparatus of claim 2, wherein the POD fan is arranged between the guide part and the hole.

4. The display apparatus of claim 3, wherein the guide part comprises a substantially duct-like structure.

5. The display apparatus of claim 3, wherein a first side of the guide part is coupled with the POD fan and a second side of the guide part is coupled with the hole.

6. The display apparatus of claim 1, wherein the hole is an air outlet.

7. The display apparatus of claim 1, wherein the guide part guides the heat from the POD fan directly to the hole provided in the rear cover to output the heat.

8. The display apparatus of claim 1, wherein the POD card-mounting part is attached with the display part in a base part of the display apparatus.

9. The display apparatus of claim 1, wherein the display part is a cathode ray tube.

10. A display apparatus, comprising:
a front cover having a display part for displaying an image attached thereon;
a rear cover coupled with the front cover and having a hole provided therein;
a circuit part attached with the front cover and/or the rear cover;
a POD card-mounting part arranged on the circuit part;
a guide part to couple the POD card-mounting part with the hole to discharge heat; and
a POD fan arranged between the POD card-mounting part and the guide part.

11. The display apparatus of claim 10, wherein the POD card-mounting part is attached with the circuit part at a base part of the display apparatus.

12. The display apparatus of claim 11, wherein the guide part faces the base part and is adjacent to the POD fan, the guide part guiding heat ventilated from the POD fan to the hole.

13. The display apparatus of claim 11, wherein a first side of the guide part faces the base part and is coupled with the POD fan and a second side of the guide part is coupled with the hole.

14. A display apparatus, comprising:
a front cover having a display part displaying an image attached thereon;
a rear cover coupled with the front cover and having a hole provided therein;
a circuit part attached with the front cover and/or the rear cover;
a POD card-mounting part arranged on the circuit part;
a guide part to couple the POD card-mounting part with the hole to discharge heat; and
a POD fan arranged between the guide part and the hole.

15. The display apparatus of claim 14, wherein the POD card-mounting part is attached with the circuit part at a base part of the display apparatus.

16. The display apparatus of claim 15, wherein the guide part faces the base part and is adjacent to the POD card-mounting part, the guide part guiding heat ventilated therethrough to the hole via the POD fan.

17. The display apparatus of claim 15, wherein a first side of the guide part faces the base part and is coupled with the POD card-mounting part and a second side of the guide part is coupled with the POD fan.
